(19) United States
(12) Patent Application Publication
(10) Pub. No.: US 2021/0108107 A1
(43) Pub. Date: Apr. 15, 2021

(54) POLISHING SLURRIES INCLUDING CERIA NANOPARTICLES AND METHODS FOR POLISHING MATERIALS USING SAME

(71) Applicant: Research Foundation for SUNY, Albany, NY (US)

(72) Inventors: Christopher Michael Netzband, Slingerlands, NY (US); Kathleen Dunn, Schenectady, NY (US)

(21) Appl. No.: 17/069,608

(22) Filed: Oct. 13, 2020

Related U.S. Application Data
(60) Provisional application No. 62/914,540, filed on Oct. 13, 2019.
(60) Provisional application No. 62/955,047, filed on Dec. 30, 2019.

(51) Int. Cl. C09G 1/02; C09G 1/16; C01F 17/235

(52) U.S. Cl. CPC C09G 1/02; B82Y 30/00; C01F 17/235; C09G 1/16

(57) ABSTRACT

Polishing slurries including ceria nanoparticles and methods of polishing materials using slurries including ceria nanoparticles. The slurries may include colloidal ceria nanoparticles having at least 20% surface concentration of Ce³⁺ oxidation state cerium atoms. The methods of polishing materials may include continuously flowing a slurry over a surface of the material. The slurry may include deionized water, colloidal ceria nanoparticles having at least 20% surface concentration of Ce³⁺ oxidation state cerium atoms, where the colloidal ceria nanoparticles include a concentration having a range of 0.01 wt. % to 3.0 wt. %, and hydrogen peroxide including a concentration having a range of 0.015 wt. % to 1.5 wt. %. The method may also include chemically and mechanically removing a portion of the material. The removed portion may include the surface of the material exposed to the slurry.

### CROSS REFERENCE TO RELATED APPLICATIONS

This application claims the benefit of U.S. Provisional Application No. 62/914,540, filed Oct. 13, 2019, and U.S. Provisional Application No. 62/955,047, filed Dec. 30, 2019—both of which are hereby incorporated herein by reference.

### BACKGROUND

The disclosure relates generally to chemical-mechanical polishing, and more particularly, to polishing slurries including ceria nanoparticles and methods of chemically-mechanically polishing materials using the same polishing slurries.

Chemical-mechanical polishing (CMP) is a method of removing layers of solid for the purpose of smoothing surfaces and the definition of various layers in the formation of semiconductors or wafers. A primary goal of the CMP process is to polish a surface of the wafer so as to render it both smooth and planar/to have a desired curvature (e.g., non-planar surfaces in lenses). In one example, CMP is a key process in back-end of line integrated circuit (IC) manufacturing. Typically, CMP is carried out using a movable pad and a slurry to polish a surface of a semiconductor or wafer. That is, in conventional CMP processes a first slurry having a large particle size and large abrasion coefficients are used to remove material. This process results in a quick removal of material, but leaves the surface rough and non-planar. To smooth and planarize the surface, a second slurry including small particle sizes and lower abrasion coefficients is used to remove the rough material, and smooth/planarize the surface.

The conventional two-part polishing process takes a significant amount of time to complete—which is especially attributed to the second step using the small particle size slurry. Furthermore, conventional CMP processes and techniques, while smoothing and mostly planarizing a surface, result in other negative effects and/or build consequences within the semiconductors or wafers. For example, dishing (see, FIG. 10A) typically occurs in metal contacts that are polished using conventional CMP processes. Dishing results in a substantial concave and/or non-planar top/contact surface in the metal contacts. The additional of subsequent materials via patterning and deposition can also cause mounding over surface topography, in addition to the dishing seen in metals. As a result, the non-planar configuration of each layer may propagate through the semiconductor stack through successive layers, negatively impacting electrical connections formed therein. To ensure substantially planar surfaces, conventional CMP processes may eliminate the use of the first step and/or the large particle size slurries, and only use the smaller particle sized slurries. While this technique may provide a smoother, more planar surface, it increases the amount of time it takes to perform the CMP technique on the semiconductor or wafer, and also increases the amount of slurry required to perform the CMP technique. This in turn increases the cost of building and/or forming semiconductors or wafers.

### BRIEF DESCRIPTION

A first aspect of the disclosure provides a polishing slurry. The polishing slurry includes: colloidal ceria nanoparticles having at least 20% surface concentration of Ce³⁺ oxidation state cerium atoms.

A second aspect of the disclosure provides a method for polishing a material. The method includes: continuously flowing a slurry over a surface of the material, the slurry including: deionized water, colloidal ceria nanoparticles having at least 20% surface concentration of Ce³⁺ oxidation state cerium atoms, the colloidal ceria nanoparticles include a concentration having a range of 0.01 wt. % to 3.0 wt. %, and hydrogen peroxide including a concentration having a range of 0.015 wt. % to 1.5 wt. %; and chemically and mechanically removing a portion of the material, the portion including the surface of the material exposed to the slurry.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows an illustrative top view of a polishing slurry including ceria nanoparticles, according to embodiments of the disclosure.

FIG. 2 shows a schematic side view of a chemical-mechanical polishing system including a wafer and polishing slurry including ceria nanoparticles, according to embodiments of the disclosure.

FIGS. 3-8 show enlarged, cross-sectional side views of the wafer and the polishing slurry of FIG. 2 undergoing chemical-mechanical polishing processes, according to embodiments of the disclosure.

FIG. 9 shows a flowchart illustrating a process for chemically-mechanically polishing a material using a polishing slurry including ceria nanoparticles, according to embodiments of the disclosure.

FIG. 10A shows a cross-sectional side view of a metal contact having undergone a conventional chemical-mechanical polishing process, according to the prior art.

FIG. 10B shows a cross-sectional side view of a metal contact having undergone a chemical-mechanical polishing process using a polishing slurry including ceria nanoparticles, according to embodiments of the disclosure.

FIG. 11A shows a cross-sectional side view of a metal contact having undergone a conventional chemical-mechanical polishing process, according to the prior art.

FIG. 11B shows a cross-sectional side view of a metal contact having undergone a chemical-mechanical polishing process using a polishing slurry including ceria nanoparticles, according to additional embodiments of the disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

As an initial matter, in order to clearly describe the current disclosure it will become necessary to select certain terminology when referring to and describing relevant machine components within the disclosure. When doing this, if possible, common industry terminology will be used and employed in a manner consistent with its accepted meaning. Unless otherwise stated, such terminology should be given a broad interpretation consistent with the context of the present application and the scope of the appended claims. Those of ordinary skill in the art will appreciate that often a particular component may be referred to using several different or overlapping terms. What may be described herein as being a single part may include and be referenced in another context as consisting of multiple components. Alternatively, what may be described herein as including multiple components may be referred to elsewhere as a single part.

As discussed herein, the disclosure relates generally to chemical-mechanical polishing, and more particularly, to polishing slurries including ceria nanoparticles and methods of chemically-mechanically polishing materials using the same polishing slurries.

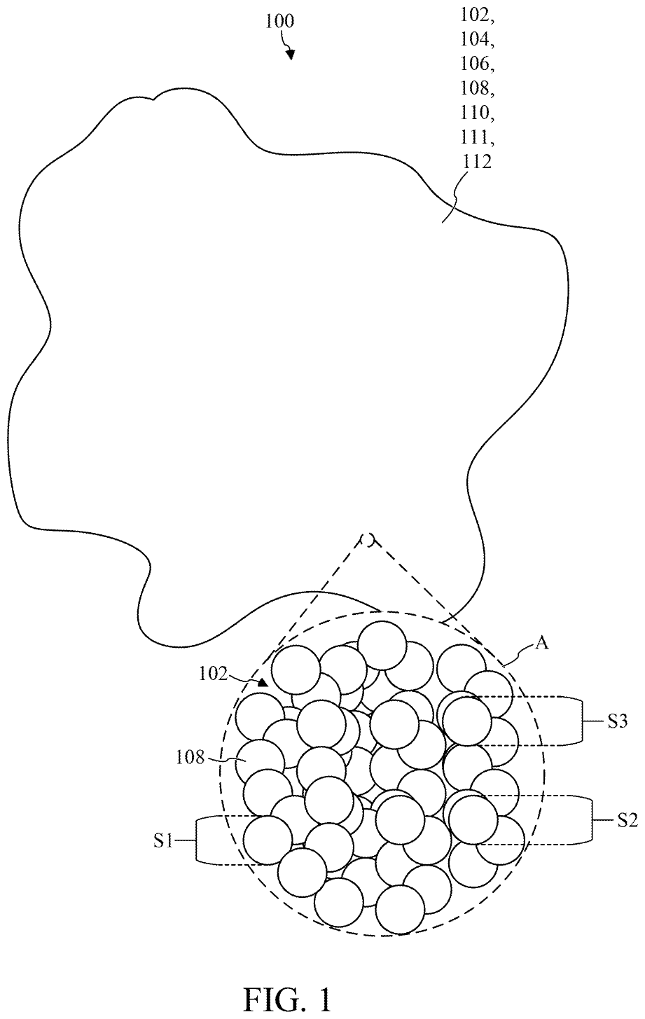

These and other embodiments are discussed below with reference to FIGS. 1-11B. However, those skilled in the art will readily appreciate that the detailed description given herein with respect to these Figures is for explanatory purposes only and should not be construed as limiting.

FIG. 1 shows a non-limiting example of a polishing slurry 100. As discussed herein polishing slurry 100 may be used to perform a chemical-mechanical polishing process on a wafer, semiconductor, and/or material that requires controlled material removal, planarization, and/or forming a desired, non-planar surface (e.g., curved lens surface). Polishing slurry 100 may be formed from a variety of materials, elements, particles, and/or additives. Polishing slurry 100 may include and/or be formed from at least a cerium-based material, a solvent, and an oxidizing agent. For example, and as discussed herein, polishing slurry 100 may be formed from a mixture of and/or may include cerium oxide or ceria 102, deionized water 104, and hydrogen peroxide (H₂O₂) 106.

Ceria 102 included within polishing slurry 100 may include and/or may be formed as a plurality of ceria nanoparticles 108. As shown in the enlarged or magnified portion “A” of polishing slurry 100, ceria nanoparticles 108 maybe colloidal, and/or polishing slurry 100 may include a colloidal dispersion of ceria nanoparticles 108 therein. Ceria nanoparticles 108 of polishing slurry 100 may including or be formed as, for example, an oxide form of elemental cerium (Ce), and may have a predetermined and/or desired surface concentration of Ce³⁺ and Ce⁴⁺ oxidation state cerium atoms. In a non-limiting example, ceria nanoparticles 108 may have at least a 20% surface concentration of Ce³⁺ oxidation state cerium atoms, and more specifically a range of surface concentration of Ce³⁺ oxidation state cerium atoms between approximately 20% and approximately 35%. As discussed herein, the surface concentration of Ce³⁺ oxidation state cerium atoms may be dependent at least in part on the size or dimension of ceria nanoparticles 108 and/or a concentration of hydrogen peroxide (H₂O₂) 106 present in polishing slurry 100. Additionally, and as discussed herein, the surface concentration of Ce³⁺ oxidation state cerium atoms for each ceria nanoparticle 108 may affect a chemical reaction between polishing slurry 100 and a material to be polished using a chemical-mechanical polishing process.

Ceria nanoparticles 108 of ceria 102 may also include a predetermined and/or predefined dimension or size (S). In one non-limiting example, colloidal ceria nanoparticles 108 may include a size (S) range of between approximately 5 nanometers (nm) and approximately 100 (nm). In this example, the size (S1, S2) of ceria nanoparticles 108 may be substantially uniform within polishing slurry 100. In another non-limiting example, colloidal ceria nanoparticles 108 may include a bimodal size distribution. The bimodal size distribution for ceria nanoparticles 108 may be separated by approximately 20 nanometers (nm), such that the bimodal size distribution for ceria nanoparticles 108 ranges between approximately 25 nanometers and approximately 45 nanometers (e.g., S1), and between approximately 80 nanometers and approximately 100 nanometers (e.g., S2), respectively. In a further non-limiting example, the colloidal ceria nanoparticles 108 may include a multimodal size distribution separated by approximately 20 nanometers. The multimodal size distribution for ceria nanoparticles 108 may range, for example, between approximately 5 nanometers and approximately 25 nanometers (e.g., S1), between approximately 40 nanometers and approximately 60 nanometers (e.g., S2), and between approximately 75 nanometers and 95 nanometers (e.g., S3), respectively. The dimension or size (S) of ceria nanoparticles 108 of ceria 102 may determine, impact, and/or influence the surface concentration of Ce³⁺ oxidation state cerium atoms included therein. For example, smaller ceria nanoparticles 108 (e.g., S=5 nm) may include a larger surface concentration of Ce³⁺ oxidation state cerium atoms, than larger ceria nanoparticles 108 (e.g., S=65 nm). In this non-limiting example larger ceria nanoparticles 108 (e.g., S=65 nm) may have a larger surface concentration of Ce⁴⁺ oxidation state cerium atoms. As discussed herein, additional material, elements, and/or additives may be added to polishing slurry 100 to interact/react with ceria nanoparticles 108 to increase the surface concentration of Ce³⁺ oxidation state cerium atoms in ceria nanoparticles 108.

Ceria 102, and more specifically ceria nanoparticles 108, includes a predetermined and/or predefined concentration weight percent (wt. %) of polishing slurry 100. In a non-limiting example, colloidal ceria nanoparticles 108 may include a concentration within a range of approximately 0.01 wt. % to approximately 3.0%. As discussed herein, the predetermined concentration of ceria nanoparticles 108 may aid and/or improve the chemical-mechanical polishing process performed on a material by reducing polishing time, improving a surface finish (e.g., smoothness, planarization characteristics), and/or reducing the amount of ceria 102 required in polishing slurry 100. The reduced amount of ceria 102 in polishing slurry 100 may ultimately reducing the cost of polishing slurry 100 and/or the amount of polishing slurry 100 required to perform the polishing process.

As shown in FIG. 1, polishing slurry 100 including ceria nanoparticles 108 may also include deionized water 104 (e.g., solvent) and/or hydrogen peroxide 106 (e.g., oxidizing agent). Similar to ceria nanoparticles 108, each of deionized water 104 and hydrogen peroxide (H₂O₂) 106 may each include a predetermined and/or predefined concentration weight percentage (wt. %). For example, the predetermined or predefined concentration weight percentage for hydrogen peroxide (H₂O₂) 106 may include a concentration within a range of approximately 0.015 wt. % to approximately 1.5 wt. %. Deionized water 104 may make up the remainder of polishing slurry 100 by weight percentage (wt. %)—absent any additional additives, materials, and/or elements to polishing slurry 100, as discussed herein.

The concentration of hydrogen peroxide (H₂O₂) 106 may be dependent upon, at least in part, the dimension or size (S) of ceria nanoparticles 108, the concentration weight percentage of ceria nanoparticles 108, and/or the surface concentration of Ce³⁺ oxidation state cerium atoms in ceria nanoparticles 108. In a non-limiting example, the concentration weight percentage (wt. %) of hydrogen peroxide (H₂O₂) 106 may be less than the concentration weight percentage (wt. %) of ceria nanoparticles 108 within polishing slurry 100. More specifically, polishing slurry 100 may include a 2:1 ratio or relationship between the weight percentage of ceria nanoparticles 108 and hydrogen peroxide (H₂O₂) 106. In this example, colloidal ceria nanoparticles 108 may include a concentration of approximately 1.0 wt. %, while hydrogen peroxide (H₂O₂) 106 includes a concentration of approximately 0.5 wt. %. In other non-limiting examples, the concentration weight percentage (wt. %) of hydrogen peroxide (H₂O₂) 106 may be substantially equal to or greater than the concentration weight percentage (wt. %) of ceria nanoparticles 108 within polishing slurry 100. The addition of hydrogen peroxide (H₂O₂) 106 to polishing slurry 100 may increase the surface concentration of Ce³⁺ oxidation state cerium atoms in ceria nanoparticles 108. That is, adding hydrogen peroxide (H₂O₂) 106 to polishing slurry 100 may result in a reaction with, and more specifically a decomposition by, ceria nanoparticles 108, similar to the action of, for example, the enzyme catalase. When the initial percentage of Ce³⁺ on the particle surface is low, this reaction increases the surface concentration of Ce³⁺ oxidation state cerium atoms in ceria nanoparticles 108 from the base and/or unreacted surface concentration of Ce³⁺ oxidation state cerium atoms for ceria 102. When the initial percentage of Ce³⁺ on the particle surface is high, the addition and decomposition of hydrogen peroxide (H₂O₂) 106 decreases the surface concentration of Ce³⁺ oxidation state cerium atoms in ceria nanoparticles 108, resulting in an increase in the percentage of Ce³⁺ oxidation state cerium atoms for ceria 102. As discussed herein, controlling the surface concentration of Ce³⁺ oxidation state cerium atoms for nanoparticles 108 in polishing slurry 100 may aid in and/or improve a chemical reaction (e.g., condensation reaction) between polishing slurry 100 and the material being chemically-mechanically polished using polishing slurry 100.

Polishing slurry 100 may also include a buffer material 110. Buffer material 110 may be added and/or included in polishing slurry 100 to adjust the pH of polishing slurry 100. More specifically, buffer material 110 may be added, included, and/or formed in polishing slurry 100 to adjust or alter the pH of polishing slurry 100 to a desired or predetermined pH. The desired or predetermined pH level of polishing slurry 100 may be dependent, at least in part, on the composition or make-up of the material undergoing the chemical-mechanical polishing process using polishing slurry 100. The pH level of polishing slurry 100, as determined or adjusted by, at least in part, buffer material 110, may be within a range of approximately pH 1 to approximately pH 12. In a non-limiting example, buffer material 110 may be added to polishing slurry 100 to adjust the pH to between approximately pH 8 and pH 10 when polishing slurry 100 is used to polish a material including copper, cobalt, ruthenium, and/or any other metal or metal-alloy material including similar material/mechanical characteristics (e.g., hardness, ductility, strength, elasticity, isoelectric point etc.). In another non-limiting example, buffer material 110 may be added to polishing slurry 100 to adjust the pH to between approximately pH 6 and pH 8 when polishing slurry 100 is used to polish a material including silicon, and/or quartz, and/or any other silica/polymer material (e.g., SiO₂, soda glass, borosilicate, other silica-based glasses) including similar material/mechanical characteristics. In a further non-limiting example, buffer material 110 may be added to polishing slurry 100 to adjust the pH to between approximately pH 1 and pH 2 when polishing slurry 100 is used to polish a material including tungsten and/or any other metal or metal-alloy material including similar material/mechanical characteristics. Still further, the pH of polishing slurry 100 may be adjusted similarly as discussed herein to polish other materials including, but not limited to, manufactured sapphire or other planar-crystalline material, gemstones, and/or naturally occurring materials that may require/undergo a polishing technique prior to use.

The pH level of polishing slurry 100 may be determined by the amount or concentration weight percentage (wt. %) of buffer material 110 added therein and/or the composition or type of buffer material 110 added to polishing slurry 100. In non-limiting examples, buffer material 110 added to polishing slurry 100 may include, but is not limited to, Potassium hydroxide (KOH), sodium hydroxide (NaOH); nitric acid (HNO₃), nitrite (NO₂⁻), sulfate (SO₄²⁻), phosphate (PO₄³⁻), ammonia (NH₃) or ammonium hydroxide (NH₄OH), and/or other suitable materials including similar material/reactive characteristics. As discussed herein, adjusting the pH of polishing slurry 100 may affect (e.g., improve) the rate of condensation reaction between ceria nanoparticles 108 in polishing slurry 100 and the material being polished by polishing slurry 100.

In the non-limiting example shown in FIG. 1, polishing slurry 100 may also include at least one surfactant 111. Surfactant(s) 111 may be added to polishing slurry 100 to aid or increase particle dispersibility within polishing slurry 100, and/or to keep nanoparticles 108 suspended in slurry 100 to prevent flocculation. Surfactant(s) 111 may be added at a predetermined or predefined concentration weight percentage (wt. %). For example, surfactant(s) 111 may include a total concentration range between approximately 0.001 wt. % and approximately 1.0 wt. %. The concentration of surfactant(s) 111 added or including within polishing slurry 100 may be dependent, at least in part, on the size of ceria nanoparticles 108, pH of slurry 100, surface charge of ceria nanoparticles 108, ionic strength of slurry 100, and/or material characteristics of surfactant(s) 111 (e.g., molecular weight, linear v. micelle-forming molecule, etc.). Surfactant(s) 111 included in polishing slurry 100 may include cationic, anionic, and/or nonionic surfactant materials. In non-limiting examples, surfactant(s) 111 may include a micellular surfactant and an ionic detergent, and/or a linear surfactant and a non-ionic or zwitterionic detergent. Furthermore, surfactant(s) 111 may also include or be formed as sodium dodecyl sulfate, sodium lauryl sulfate, sodium lauryl ether sulfate, sodium myreth sulfate, sodium pareth sulfate, potassium lauryl sulfate, ammonium lauryl sulfate, hexadecyltrimethylammonium bromide, a polyvinylpyrrolidone, a polyethylene glycol and/or an amino acid.

Polishing slurry 100, as shown in FIG. 1, may also include supplemental additive(s) 112. Supplemental additive(s) 112 may be added and/or included within polishing slurry 100 to aid in the chemical-mechanical polishing of a material, as discussed herein. Supplemental additives 112 may be present and/or included in polishing slurry 100 based, at least in part, the composition of the material being polished using polishing slurry 100. For example, where the material being polished is copper or copper-based, supplemental additive(s) 112 (e.g., glycine) may be added and/or included within polishing slurry 100 to aid in the chemical removal process, as discussed herein. In this non-limiting example, supplemental additive(s) 112 formed as glycine may chemically decompose, break down, and/or remove at least a portion of the material being polished using polishing slurry 100.

Although shown in FIG. 1 as including all additives, materials, and/or elements, it is understood that polishing slurry 100 may include less materials than those shown. That is, the composition of polishing slurry 100 may not include all additives/materials 102, 104, 106, 110, 111, 112 as shown in FIG. 1. For example, polishing slurry 100 may not include surfactant(s) 111 where particle dispersibility within polishing slurry 100 is acceptable without the additive. In another non-limiting example, buffer material 110 may not be included in and/or added to polishing slurry 100 where the pH of polishing slurry 100 including ceria 102, deionized water 104, and hydrogen peroxide 106 is within the desired or predetermined range for the material being polished. In view of this, it is understood that the composition of polishing slurry 100 shown in FIG. 1 is illustrative and may differ from that shown depending upon the material and/or the chemical-mechanical process being performed.

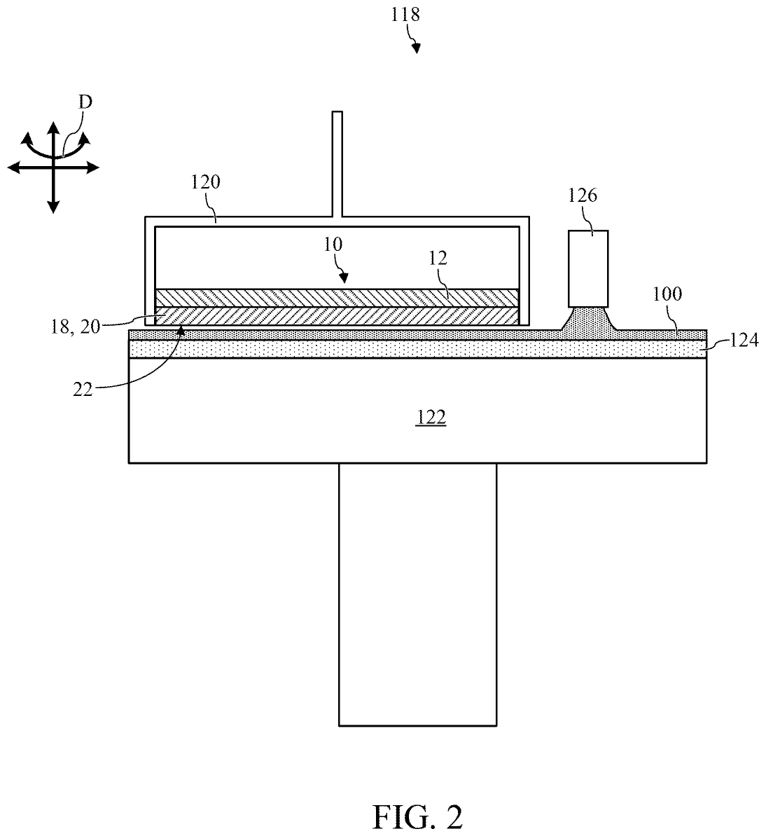

Turning to FIG. 2, a polishing system 118 is shown. Polishing system 118 may be used to perform a chemical-mechanical polishing process on a semiconductor or wafer 10 (hereafter, “wafer 10”). In the non-limiting example shown, wafer 10 may be partially build and/or may be shown in the intermediate stages of build. That is, wafer 10 may include substrate 12, and a first layer 18 of material 20 disposed over substrate 12 (e.g., wafer is held in polishing system 118 upside-down). First layer 18 of material 20 may include surface 22. Material 20 may include any suitable material used to form, build, and/or create wafer 10. In a non-limiting example, material 20 may be formed from silicon, silicon oxides, polymers, metal (copper, cobalt, ruthenium, tungsten, etc.), metal-alloys, metal oxides (Hafnium oxide (HfO₂)), metal nitrides (Tantalum nitride (TaN), or titanium nitride (TiN)), or the like. As discussed herein, the predetermined particle size of ceria nanoparticles 108 in polishing slurry 100, and/or the predetermined pH of polishing slurry 100 may be dependent upon the type or composition of material 20.

Polishing system 118 may include wafer carrier 120. Wafer carrier 120 may hold and/or move wafer 10 during the polishing process as discussed herein. As shown in FIG. 2, polishing system 118 may also include a platen 122 positioned opposite wafer carrier 120, and a polishing pad 124 disposed over and/or substantially covering platen 122. Polishing pad 124 may be positioned between platen 122 and wafer carrier 120/wafer 10 held within carrier 120. Polishing system 118 may further include a slurry deposition device 126. Slurry deposition device 126 may deposit, dispose, and/or continuously flow polishing slurry 100 on or over polishing pad 124 during the chemical-mechanical polishing process performed on wafer 10. In the non-limiting example, wafer carrier 120 and/or platen 122 may configured to move in various directions (D) to perform chemical-mechanical polishing process on material 20 and/or surface 22 of wafer 10. Additionally, carrier 120 may be configured to move wafer 10 toward and/or apply a force/pressure between wafer 10 and polishing slurry 100 continuously flowing over polishing pad 124 during the chemical-mechanical polishing process discussed herein.

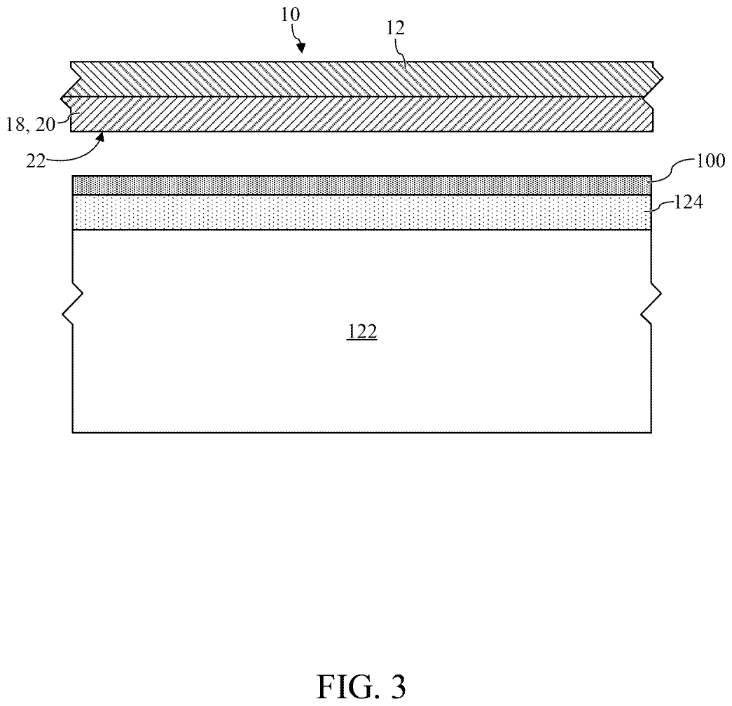

FIGS. 3-8 show enlarged, cross-sectional side views of wafer 10 and polishing slurry 100 of FIG. 2 undergoing chemical-mechanical polishing processes using polishing system 118. More specifically, FIGS. 3-8 show wafer 10 undergoing multiple build and chemical-mechanical polishing processes using polishing slurry 100 within polishing system 118. It is understood that similarly numbered and/or named components may function in a substantially similar fashion. Redundant explanation of these components has been omitted for clarity.

FIG. 3 Shows a non-limiting example of wafer 10 positioned above and adjacent to polishing slurry 100 flowing over polishing pad 124. In this example, wafer carrier 120 has not positioned and/or moved wafer 10 to contact polishing slurry 100. More specifically, surface 22 of first layer 18 of material 20 is separated from and/or has not contacted or been exposed to polishing slurry 100 continuously flowing over polishing pad 124 of polishing system 118.

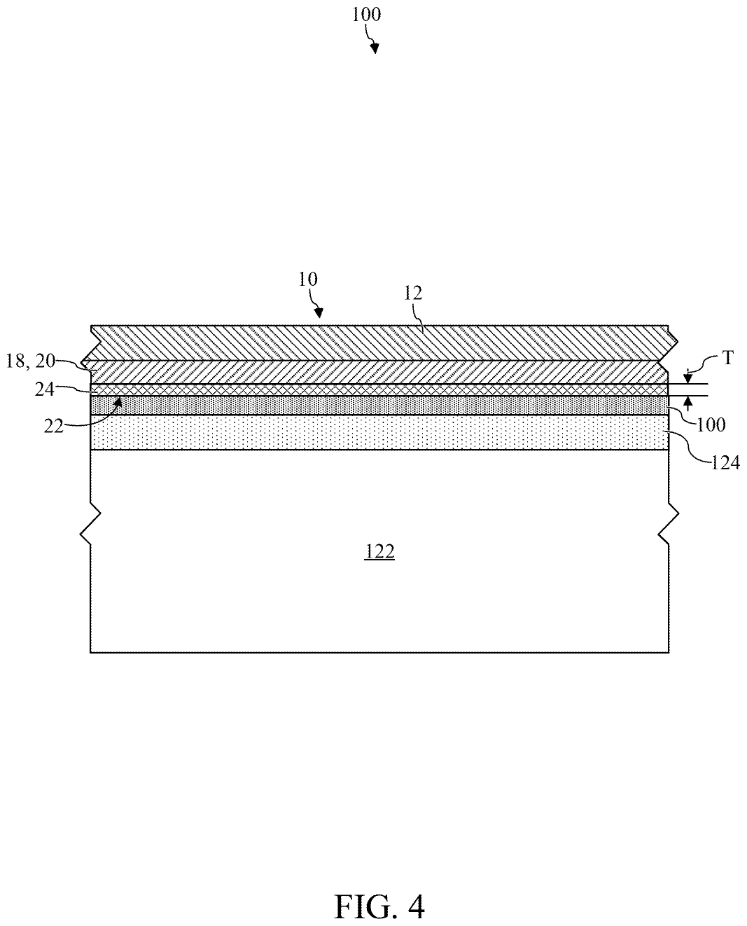

FIG. 4 shows wafer 10 contacting and/or being exposed to polishing slurry 100. More specifically, surface 22 of first layer 18 of material 20 may contact and/or be directly exposed to polishing slurry 100 continuously flowing over and/or between polishing pad 124 of polishing system 118 and wafer 10. As discussed herein, wafer carrier 120 may move wafer 10 to contact and/or be exposed to polishing slurry 100. In the non-limiting example, contacting and/or exposing surface 22 of first layer 18 formed from material 20 may result in the formation of an oxidized portion 24 of material 20. More specifically, exposing material 20 to polishing slurry 100 including ceria nanoparticles 108 having a predetermined surface concentration of Ce³⁺ oxidation state cerium atoms may result in a condensation reaction occurring at the surface 22 of first layer 18 of material 20. The condensation reaction may be between ceria nanoparticles 108 of polishing slurry 100 continuously flowing over an oxidized portion 24 of surface 22, and material 20 forming first layer 18 of wafer 10. Exposing material 20 to polishing slurry 100 including hydrogen peroxide (H₂O₂) 106 may result in a portion of material 20 forming first layer 18 to be oxidized (e.g., oxidized portion 24), which in turn may undergo a condensation reaction with ceria nanoparticles 108. The condensation reaction between nanoparticles 108 of polishing slurry 100 and material 20 forming first layer 18 of wafer 10 may be instantaneous after polishing slurry 100 contacts material 20. The rate of the condensation reaction may also be influenced and/or determined by the pH of polishing slurry 100. That is, and as discussed herein, polishing slurry including ceria nanoparticles 108 may include a predetermined, predefined, and/or desired pH that may aid and/or ensure a high/substantially immediate condensation reaction between polishing slurry 100 and material 20.

In the non-limiting example where material 20 is formed from copper (Cu), oxidized portion 24 formed via a redox reaction may be formed as copper oxide (Cu₂O or CuO), while the remainder of first layer 18 may remain copper (Cu). The penetration depth or thickness (T) of oxide portion 24 formed in first layer 18 may be predetermined and/or calculated based on a variety of operational parameters and/or characteristics. For example, and as discussed herein, the thickness (T) of oxide portion 24 may be dependent, at least in part on, the concentration of hydrogen peroxide (H₂O₂) 106 within polishing slurry 100, the pH of polishing slurry 100 flowing over surface 22 of material 20 for wafer 10, and/or exposure time. Additionally, during the polishing process the reduction of thickness (T) of oxide portion 24 formed in first layer 18 for wafer 10 is dependent on the size (S) and concentration of ceria nanoparticles 108 included within polishing slurry 100, applied force/pressure to wafer 10 into polishing slurry 100, and/or movement characteristics of carrier 120/platen 122 (e.g., direction of movement, speed, vibration, etc.).

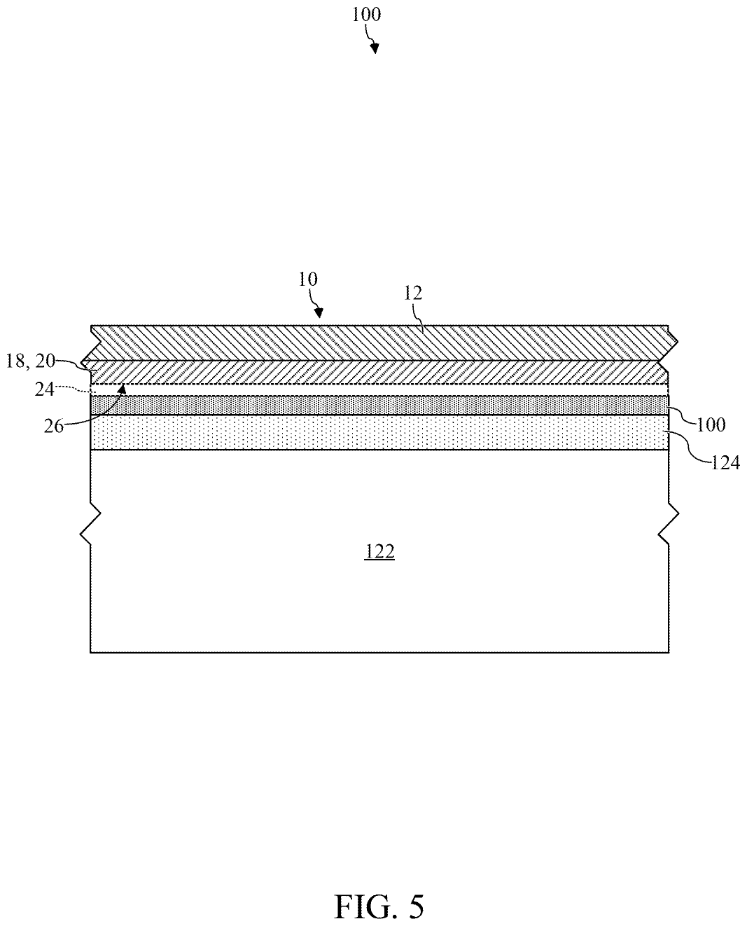

FIG. 5 shows wafer 10 post polishing. More specifically, FIG. 5 shows wafer 10 after finalizing the chemical-mechanical polishing process on oxidized portion 24 of first layer 18 formed from material 20. In the non-limiting example, oxidized portion 24 is shown in phantom as being removed and/or no longer present in first layer 18 of wafer 10. As such, first layer 18 of wafer 10 may include the remaining portion of first layer 18 formed from material 20 (e.g., copper), and may have a new/desired thickness (compare, FIG. 5 with FIG. 3). Additionally, chemically-mechanically removing oxidized portion 24 of first layer 18 formed from material 20 may also result in the formation of a polished surface 26 for first layer 18. Polished surface 26 for first layer 18 of wafer 10 may include a substantially smooth/planarized surface (e.g., less than 4 nanometer deviation in surface non-uniformity).

Oxidized portion 24 of first layer 18 formed from material 20 may be removed using one of, or a combination of, chemical and/or mechanical reactions/responses. For example, at least a section of oxidized portion 24 may be removed from first layer 18 via a chemical reaction within oxidized material 20. That is, and based on the exposure to ceria nanoparticles 108 of polishing slurry 100 and the resulting condensation reaction occurring therebetween, at least a section of oxidized portion 24 may, break down, and/or be removed from the remainder of oxidized portion 24 and/or the remaining portion of first layer 18. Additionally, or alternatively, oxidized portion 24 (or the remaining section of oxidized portion 24) may be mechanically abraded away from the remainder of material 20 forming first layer 18 of wafer 10. That is, the abrasive properties of ceria nanoparticles 108 of polishing slurry 100, as well as the operational characteristics/parameters of polishing system 118 (e.g., movement of carrier 120 and/or polishing pad 124, pressure of wafer 10 against polishing slurry 100) may result in the abrading, eroding, and/or removal of oxidized portion 24 from the remainder of first layer 18 of wafer 10. In addition to the removal of oxidized portion 24, the abrasive properties of ceria nanoparticles 108 of polishing slurry 100, as well as the operational characteristics/parameters of polishing system 118 may result in the formation of polished surface 26 in first layer 18 of wafer 10.

Although shown as forming oxidized portion 24 in FIG. 4, and the subsequent removal of oxidized portion 24 to form polished surface 26 in FIG. 5 in a single step or process, it is understood that the polishing of first layer 18 and formation of polished surface 26 may occur in multiple stages. That is, as polishing slurry 100 continuously flows over first layer 18, multiple oxidized portions 24 may be formed in first layer 18 and subsequently removed via the chemical-mechanical polishing process performed using polishing slurry 100 and polishing system 118. The oxidizing and removal processes may continuously occur, removing small sections or “layers” of identified oxidized portion 24, until the removed oxidized portion 24 includes the desired thickness (T), and/or the remaining portion of first layer 18 includes a desired thickness. As such, the formation and subsequent removal of oxidized portion 24 may stop when polishing slurry 100 is no longer flowing over first layer 18, and polishing system 118 is no longer operating to polish first layer 18.

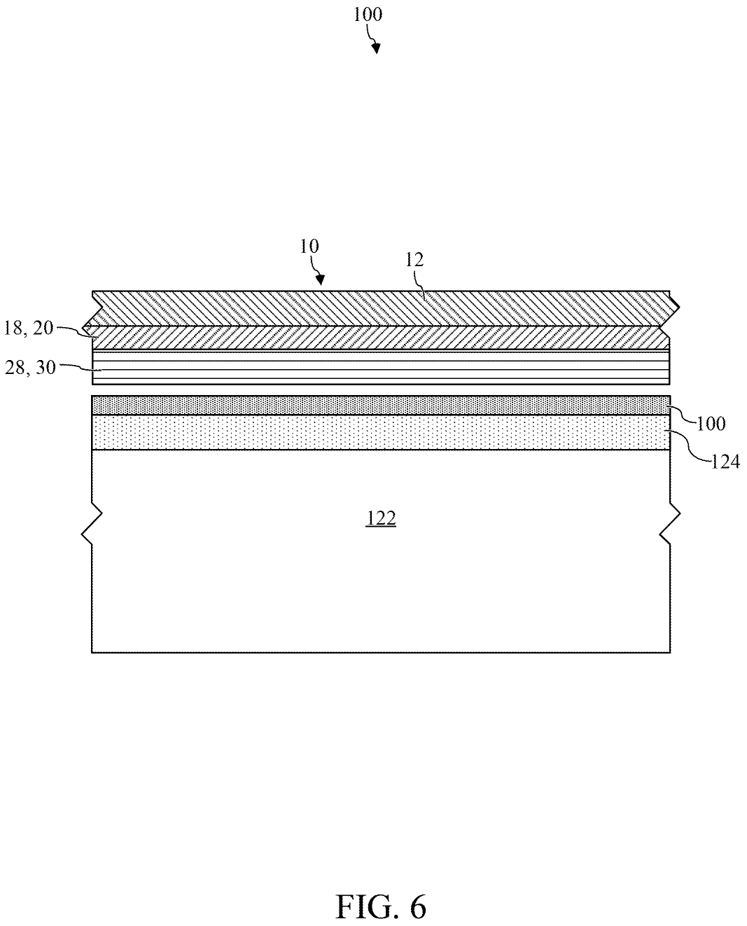

FIGS. 6-8 show additional, non-limiting examples of wafer 10 undergoing a build and subsequent chemical-mechanical polishing processes. In FIG. 6, wafer 10 may include a second layer 28 of material 30 formed and/or disposed over first layer 18. Material 30 forming second layer 28 may be formed from a material or composition that may be distinct from material 20 forming first layer 18. Continuing the example, where material 20 forming first layer 18 is copper (Cu), material 30 forming second layer 28 may be formed from silicon (Si). As discussed herein, to improve in the chemical-mechanical polishing process, polishing slurry 100 may have a predetermined, predefined, and/or desired pH that is based on the composition and/or make-up of the material undergoing the polishing process. As a result, polishing slurry 100 used to chemically-mechanically polish second layer 28 may include a distinct pH from polishing slurry 100 used to chemically-mechanically polish first layer 18. In a non-limiting example, pH of polishing slurry 100 may be adjusted by adding additional buffer material 110 (see, FIG. 1) to reach the predetermined/desired pH, before polishing second layer 28. In another non-limiting example, distinct polishing slurry 100 including the predetermined/desired pH may be supplied to polishing system 118 in order to polish second layer 28. In this example, the distinct polishing slurry 100 including the distinct, predetermined pH to polish second layer 28 may include substantially the same or distinct characteristics (e.g., size of ceria nanoparticles 108, amount of surfactant, etc.) as polishing slurry 100 utilized to polish first layer 18.

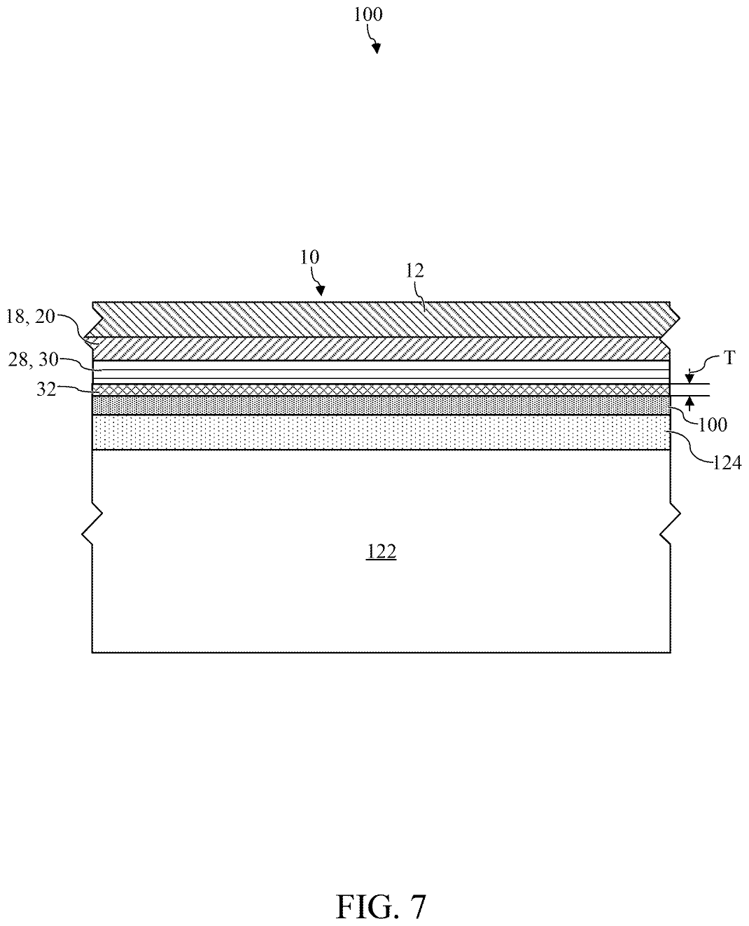

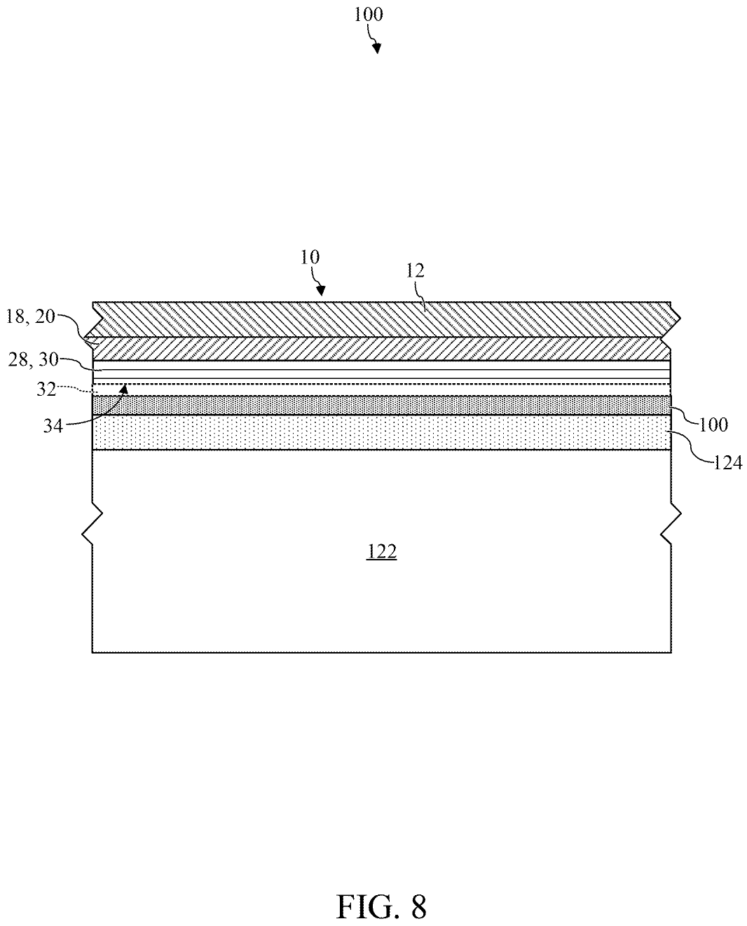

FIGS. 7 and 8 show second layer 28 undergoing the chemical-mechanical polishing processes using polishing slurry 100. The process and results may be substantially similar to those shown and discussed herein with respect to FIGS. 4 and 5. That is, exposure to and/or contacting second layer 28 to polishing slurry 100 may result in a condensation reaction between material 30 forming second layer 28 and polishing slurry 100 include ceria nanoparticles 108. Additionally, a redox reaction with hydrogen peroxide (H₂O₂) 106 may result in the formation of oxidized portion 32 in second layer 28 (see, FIG. 7). Oxidized portion 32 formed in second layer 28 may also be removed from the remainder of second layer 28 (see, FIG. 8, shown in phantom) via the chemical-mechanical removal using polishing slurry 100 in polishing system 118. Finally, polished surface 34 may be formed on second layer 28 of wafer 10 as a result of chemically-mechanically polishing second layer 28. It is understood that the formation and removal of oxidized portion 32 in second layer 28 of wafer 10 may be accomplished in a substantially similar fashion as that discussed herein with respect to oxidized portion 24 of first layer 18. Redundant explanation of these processes has been omitted for clarity.

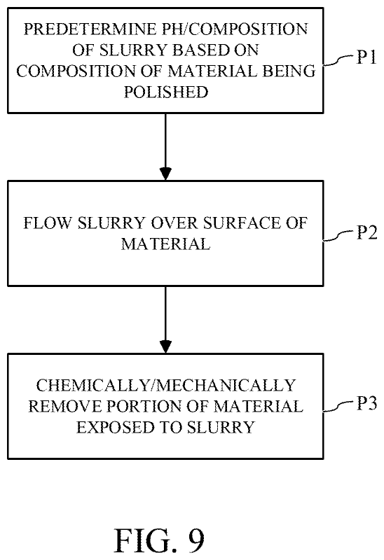

FIG. 9 depicts example processes for chemically-mechanically polishing a material. More specifically, FIG. 9 depicts a non-limiting example of processes for chemically-mechanically polishing a material using a polishing slurry that includes ceria nanoparticles. The polishing slurry used in these processes may be substantially similar to slurry 100 shown and discussed herein with respect to FIGS. 1-8.

In process P1, a pH and/or a composition of the polishing slurry may be predetermined. That is, a pH of the polishing slurry used by a polishing system to chemically-mechanically polish a material may be predetermined, predefined, and/or precalculated. The predetermined pH may be dependent or based on a composition of the material being polished using the polishing slurry. Predetermining the pH of the polishing slurry may also include ensuring and/or (compositionally) modifying the polishing slurry such that the actual pH of the slurry matches the predetermined pH. The pH of the polishing slurry may be modified, for example, using a buffer material.

Additionally, or alternatively, a composition of the polishing slurry used by a polishing system to chemically-mechanically polish a material may be predetermined, predefined, and/or analyzed. Similar to the pH, the composition of the polishing slurry may be dependent or based on a composition of the material being polished using the polishing slurry. That is, the composition of the polishing slurry may be predetermined and/or analyzed based on the material to be polished to determine if additional materials, elements, particles, and/or additives (e.g., supplemental additives) should be added to the polishing slurry prior to the flowing (e.g., process P2). In response to determining that the polishing slurry does not include the composition desired and/or required to polish the material, predetermining the composition of the polishing slurry may also include modifying the polishing slurry such that the composition of the slurry matches the predetermined, desired, and/or required composition. For example, where copper is the material to be polished, supplemental additives may be added to the polishing slurry to aid in the chemically-mechanically polish (e.g., process P3) the copper as desired.

In process P2 polishing slurry may be flowed over a surface of the material being polished. More specifically, polishing slurry may be continuously flowed over the surface of the material undergoing the chemical-mechanical polish. The polishing slurry may include the predetermined pH that is based on the material. Additionally, the polishing slurry may include deionized water and colloidal ceria nanoparticles. In a non-limiting example, the ceria nanoparticles of the polishing slurry may have at least 20% surface concentration of Ce³⁺ oxidation state cerium atoms. Additionally, the colloidal ceria nanoparticles may include a concentration having a range of 0.01 wt. % to 3.0 wt. %. Finally, the polishing slurry may also include hydrogen peroxide (H₂O₂) including a concentration having a range of 0.015 wt. % to 1.5 wt. %.

In process P3, a portion of the material may be chemically and mechanically removed. The portion chemically and mechanically removed may include the surface of the material exposed to the polishing slurry. In a non-limiting example, the chemical and mechanical removal of the portion of the material may also include the oxidation of the surface of the material in response to continuously flowing the polishing slurry over the surface of the material, and subsequently causing or creating a condensation reaction between the newly formed or existing oxidized surface of the material and the ceria nanoparticles, resulting in material attaching to the surface of the ceria nanoparticles and detaching from the surface being polished. That is, and as a result of the size of the ceria nanoparticles, the surface concentration of Ce³⁺ oxidation state ceria atom for the ceria nanoparticles, the presence of the hydrogen peroxide (H₂O₂) in the polishing slurry, and/or the pH of the polishing slurry, a condensation reaction between the polishing slurry and the material may take place, and result in a portion of the material being removed from the surface. In the non-limiting example, the chemical and mechanical removal of the portion of the material may further include (chemically) breaking down, and/or removing the oxidized portion from the remainder of the material, and/or abrading, eroding, and/or removing the oxidized portion from the remainder of the material. Furthermore, chemically and mechanically removing the (oxidized) portion may also include forming a smooth, polished surface on the material.

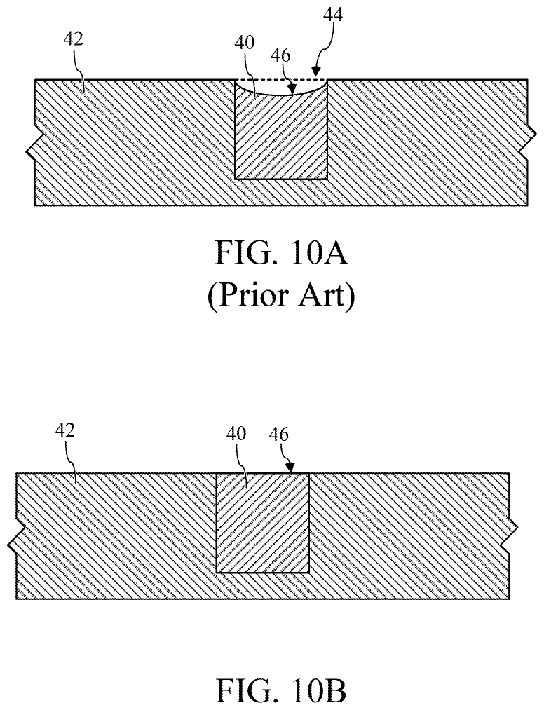

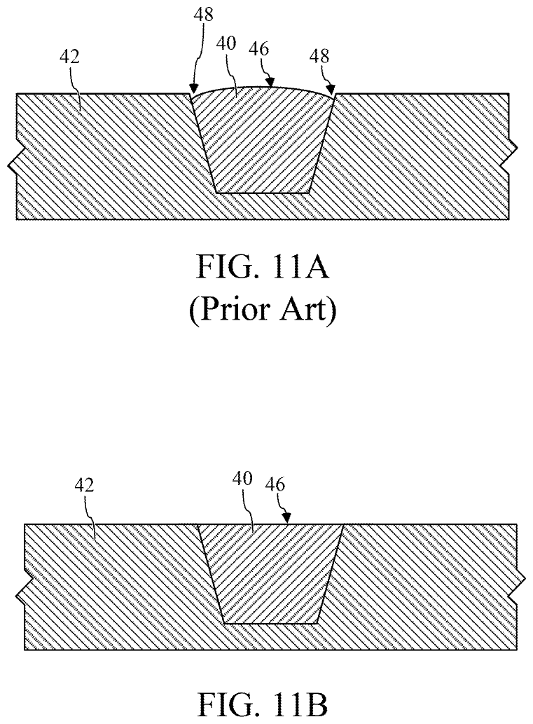

FIGS. 10A-11B show various embodiments comparing the performance of conventional chemical-mechanical polishing techniques with the performance of the chemical-mechanical polishing processes discussed herein using a polishing slurry including, amongst other material, ceria nanoparticles. For example, FIG. 10A shows a side cross sectional view of a metal (e.g., copper) contact 40 formed in a substrate 42. Metal contact 40 was polished using a conventional two-step chemical-mechanical polishing technique (e.g., large particle abrasive, then small particle abrasive). As a result of planarizing and polishing using conventional techniques, a dishing effect 44 may occur or be present in metal contact 40. That is, while substrate may be substantially planar, the top surface 46 of metal contact 40 may be a non-planar orientation and/or may have a sloped geometry.

By comparison, FIG. 10B shows a side cross sectional view of metal (e.g., copper) contact 40 formed in substrate 42 having undergone the chemical-mechanical polishing process discussed herein with respect to FIGS. 1-9. That is, metal contact 40 may be chemically-mechanically polished using polishing slurry 100 including, for example, ceria nanoparticles 108, deionized water 104, and hydrogen peroxide (H₂O₂) 106. As shown in FIG. 10B, metal contact 40 and substrate 42 may be substantially planar and/or flat as a result of polishing metal contact 40 with polishing slurry 100.

FIG. 11A shows a side cross sectional view of another non-limiting example of metal (e.g., copper) contact 40 formed in substrate 42. As shown, substrate 42 may include substantially sloped side walls for receiving metal contact 40. Similar to FIG. 10A, metal contact 40 shown in FIG. 11A was polished using a conventional two-step chemical-mechanical polishing technique. As a result polishing using conventional techniques, a gap 48 may be formed between top surface 46 of metal contact 40 and substrate 42. That is, performance of conventional chemical-mechanical polishing technique on metal contact 40 shown in FIG. 11A may result in an undesirable gap 48 being formed adjacent the interface of surface 46 of metal contact and substrate 42.

By comparison, FIG. 11B shows a side cross sectional view of metal contact 40 formed in substrate 42 having undergone the chemical-mechanical polishing process discussed herein with respect to FIGS. 1-9. As shown in FIG. 11B, metal contact 40 and substrate 42 may be substantially planar and/or flat as a result of polishing metal contact 40 with polishing slurry 100, and gap 48 shown in FIG. 11A is non-existent/non-present.

In addition to the operational/manufacturing improvements shown and discussed herein, the use of polishing slurry 100 discussed herein with respect to FIGS. 1-9 may also reduce processing time and expenses. For example, because the use of polishing slurry 100 does not require a two-part process (e.g., conventional chemical-mechanical polishing) chemically-mechanically polishing material using polishing slurry 100 may reduce the polishing time for materials. Additionally, because of the amount of ceria nanoparticles 108 present within polishing slurry 100 (e.g., 0.01 wt. % to 3.0 wt. %), the cost of producing polishing slurry 100 may be reduced or less than slurries used in conventional chemical-mechanical polishing.

The foregoing drawings show some of the processing associated according to several embodiments of this disclosure. In this regard, each drawing or block within a flow diagram of the drawings represents a process associated with embodiments of the method described. It should also be noted that in some alternative implementations, the acts noted in the drawings or blocks may occur out of the order noted in the figure or, for example, may in fact be executed substantially concurrently or in the reverse order, depending upon the act involved. Also, one of ordinary skill in the art will recognize that additional blocks that describe the processing may be added.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A polishing slurry, comprising:
colloidal ceria nanoparticles having at least a 20% surface concentration of Ce³⁺ oxidation state cerium atoms.

2. The polishing slurry of claim 1, wherein the colloidal ceria nanoparticles having the surface concentration of Ce³⁺ oxidation state cerium atoms within a range of approximately 20% and approximately 35%.

3. The polishing slurry of claim 1, wherein the colloidal ceria nanoparticles include a size range of between approximately 5 nanometers (nm) and approximately 100 nm.

4. The polishing slurry of claim 3, wherein the colloidal ceria nanoparticles include a bimodal size distribution separated by approximately 20 nm, the bimodal size distribution between approximately 25 nm and approximately 45 nm, and between approximately 80 nm and approximately 100 nm.

5. The polishing slurry of claim 4, wherein the colloidal ceria nanoparticles include a multimodal size distribution separated by approximately 20 nm.

6. The polishing slurry of claim 1, further comprises:
deionized water, wherein the colloidal ceria nanoparticles include a concentration having a range of 0.01 wt. % to 3.0 wt. %; and
hydrogen peroxide including a concentration having a range of 0.015 wt. % to 1.5 wt. %.

7. The polishing slurry of claim 6, wherein the colloidal ceria nanoparticles include a concentration of 1.0 wt. % and the hydrogen peroxide includes a concentration of 0.5 wt. %.

8. The polishing slurry of claim 6, further comprising a buffer material, the buffer material adjusting a pH of the polishing slurry to be within a range of pH 1 to pH 12.

9. The polishing slurry of claim 8, wherein the pH of the polishing slurry is within a range of pH 8 to pH 10 when polishing a material including at least one of copper, cobalt or ruthenium.

10. The polishing slurry of claim 8, wherein the pH of the polishing slurry is within a range of pH 6 to pH 8 when polishing a material including silicon.

11. The polishing slurry of claim 8, wherein the pH of the polishing slurry is within a range of pH 1 to pH 2 when polishing a material including tungsten.

12. The polishing slurry of claim 6, further comprising:
at least one surfactant, the at least one surfactant including a total concentration range of 0.001 wt. % to 1 wt. %.

13. The polishing slurry of claim 12, wherein the at least one surfactant includes a micellular surfactant and an ionic detergent.

14. The polishing slurry of claim 13, wherein the at least one surfactant is selected from a group consisting of an anionic surfactant, and a cationic surfactant.

15. The polishing slurry of claim 14, wherein the at least one surfactant is selected from a group consisting of: sodium dodecyl sulfate, sodium lauryl sulfate, sodium lauryl ether sulfate, sodium myreth sulfate, sodium pareth sulfate, potassium lauryl sulfate, ammonium lauryl sulfate, and hexadecyltrimethylammonium bromide.

16. The polishing slurry of claim 12, wherein the at least one surfactant includes a linear surfactant and a non-ionic or zwitterionic detergent.

17. The polishing slurry of claim 16, wherein the at least one surfactant is selected from a group consisting of a polyvinylpyrrolidone, a polyethylene glycol and an amino acid.

18. A method for polishing a material, the method comprising:
continuously flowing a slurry over a surface of the material, the slurry including:
deionized water,
colloidal ceria nanoparticles having at least 20% surface concentration of Ce³⁺ oxidation state cerium atoms, the colloidal ceria nanoparticles include a concentration having a range of 0.01 wt. % to 3.0 wt. %, and
hydrogen peroxide including a concentration having a range of 0.015 wt. % to 1.5 wt. %; and
chemically and mechanically removing a portion of the material, the portion including the surface of the material exposed to the slurry.

19. The method of claim 18, further comprising:
predetermining at least one of a pH of the slurry or a composition of the slurry prior to continuously flowing the slurry over the surface of the material, the predetermined pH of the slurry based on a composition of the material.

20. The method of claim 18, wherein chemically and mechanically removing the portion of the material further includes:
oxidizing the portion of the material exposed to the slurry in response to continuously flowing the slurry over the surface;
causing a condensation reaction between the slurry nanoparticles and the surface of the oxidized material; and
abrading away the oxidized portion of the material.
